(19) United States
(12) Patent Application Publication
(10) Pub. No.: US 2012/0060924 A1
(43) Pub. Date: Mar. 15, 2012

(54) METHODS AND SYSTEMS FOR FORMING FUNCTIONALLY GRADED FILMS BY SPRAY PYROLYSIS

(75) Inventors: Yuriy B. Matus, Pleasanton, CA (US); Roman Mostovoy, San Francisco, CA (US)

(73) Assignee: Alion, Inc., Richmond, CA (US)

(21) Appl. No.: 13/226,200

(22) Filed: Sep. 6, 2011

Related U.S. Application Data
(60) Provisional application No. 61/381,355, filed on Sep. 9, 2010.

(51) Int. Cl. H01L 31/0272; B05B 1/00; B05B 15/00; H01L 31/18

(52) U.S. Cl. 136/260; 438/95; 438/94; 118/58; 257/E31.015

(57) ABSTRACT

Method and system for forming a plurality of cadmium-sulfide layers. The method includes preparing a first solution and a second solution. The method further includes loading at least the first solution and the second solution into a pyrolysis-deposition system and placing a target structure into the pyrolysis-depositions system. The method further includes spraying the first solution through one or more first nozzles towards the target structure, forming, from the sprayed first solution, the first cadmium-sulfide layer, directly or indirectly, on the target structure, spraying the second solution through one or more second nozzles towards the target structure with at least the first cadmium-sulfide layer, and forming, from the sprayed second solution, the second cadmium-sulfide layer directly or indirectly, on the target structure. The first cadmium-sulfide layer includes a first cadmium-sulfide material the second cadmium-sulfide layer includes a second cadmium-sulfide material that are different in at least one material property.

### 1. CROSS-REFERENCES TO RELATED APPLICATIONS

This application claims priority to U.S. Provisional Application No. 61/381,355, filed Sep. 9, 2010, commonly assigned and incorporated by reference herein for all purposes.

The following two commonly-owned co-pending applications, including this one, are being filed concurrently and the other one is hereby incorporated by reference in its entirety for all purposes.

1. U.S. patent application Ser. No. ______, titled “Methods and Systems for Spray Pyrolysis with Addition of Volatile Non-Polar Materials,” (Attorney Docket Number 012805-0010-999); and

2. U.S. patent application Ser. No. ______, titled “Methods and Systems for Forming Functionally Graded Films by Spray Pyrolysis,” (Attorney Docket Number 012805-0012-999).

### 2. Background of the Invention

The present invention is directed to deposition of films using spray pyrolysis. More particularly, the invention provides methods and systems for forming functionally graded films using spray pyrolysis. Merely by way of example, the invention has been applied to the spray pyrolysis of functionally graded CdS films for photovoltaic modules. But it would be recognized that the invention has a much broader range of applicability.

FIG. 1 is a simplified diagram of a conventional photovoltaic module (e.g., solar cell). As shown in FIG. 1, the conventional photovoltaic module 1 is formed using four layers on top of a substrate 10. Each of the layers serves a different function. The conventional photovoltaic module it typically formed on a substrate 10, such as glass. The substrate 10 is generally about 3 mm in thickness and is transparent to allow the light source (i.e., the sun) that illuminates the photovoltaic module 1 to pass through to the active layers below. The substrate 10 also forms what is generally referred to as the front side of photovoltaic module 1. The first layer generally formed on the substrate 10 is one or more front electrodes 20 formed using a transparent conductive oxide (i.e., TCO). The one or more front electrodes 20 are typically between 200 nm and 700 nm in thickness. A cadmium sulfide (i.e., CdS) layer 30 is typically formed over the layer containing the front electrodes 20. The CdS layer 30 is typically between 50 nm and 400 nm in thickness. A cadmium telluride (i.e., CdTe) layer 40 is typically formed over the CdS layer 30. The CdTe layer is typically between 1000 nm and 5000 nm in thickness. A back electrode layer 50 is typically formed over the CdTe layer 40. The back electrode layer 50 typically contains one or more back electrodes and is formed using one or more metals. The back electrode layer 50 is also typically between 100 nm and 3000 nm in thickness.

Various deposition techniques can be used to form the various layers in the conventional photovoltaic module. For example, these deposition techniques can be divided into two groups—deposition techniques that use vacuum systems and deposition techniques that use non-vacuum systems. The deposition techniques that use vacuum systems can fabricate cadmium sulfide layers that have excellent properties, but these techniques also require expensive and complex equipment. The deposition techniques that use non-vacuum systems include a chemical bath deposition (CBD) technique and a spray pyrolysis technique. For example, the CBD technique provides excellent film quality, but the CBD technique suffers from low chemical utilization and also needs extensive waste treatment. In another example, the conventional spray pyrolysis technique provides excellent film quality, but the conventional spray pyrolysis technique suffers from a low equipment throughput (i.e., low deposition rate).

FIG. 2 is a simplified diagram of a conventional system for deposition of films on a substrate using spray pyrolysis. For example, the spray pyrolysis apparatus 100 uses one or more spray nozzles 110 to spray a pyrolysis solution 120 towards a substrate 130 positioned via a substrate holder 150. Each droplet of the pyrolysis solution 120 includes a solvent and one or more solutes depending upon the type of film to be deposited on the substrate 130. Various modes are used to obtain the film using spray pyrolysis. In one mode, as one or more droplets of the pyrolysis solution 120 approach the surface of the substrate 130, the solvent vaporizes and the one or more solutes become one or more vapors. Then, the one or more vapors form a film on the surface of the substrate 130. In another mode, one or more droplets of the pyrolysis solution 120 reach the surface of the substrate 130. Then, with the solvent still present on the surface of the substrate 130, a film is formed on the surface of the substrate 130. It is also possible for both of the two modes described above to occur in the same deposition process. The spray pyrolysis also utilizes a gas supply 170 made available to the one or more spray nozzles 110 to atomize the pyrolysis solution 120 and/or to control the flow of the pyrolysis solution through the one or more spray nozzles 110 towards the substrate 130. For example, nitrogen gas is often used.

Various techniques have been used to control the deposition modes for spray pyrolysis. For example, the temperature of the substrate 130 is adjusted through the use of one or more heating elements 140 to control the vaporization of the solvents in the pyrolysis solution 120. In another example, adjusting the distance between the one or more spray nozzles 110 and the substrate 130 controls the extent to which the gasification of the one or more solutes occurs above or on the surface of the substrate 130. In yet another example, overspray can be reduced and material utilization can be increased by the introduction of a bias voltage 160 between the one or more spray nozzles 110 and the substrate 130.

Deposition of films using conventional spray pyrolysis, however, has its limitations. For example, while the use of the one or more heating elements 140 with the conventional pyrolysis solution 120 may improve the deposition rate, and thus the production rates of the films on the substrate 130, it is not without practical limits. Heating the substrate 130 to high temperatures with the one or more heating elements 140 often has a high energy cost. It can further increase the likelihood that the substrate 130 will crack during the pyrolysis process. Thus, it would be helpful if the same deposition rates could be obtained at a lower temperature, which can lower energy costs and/or reduce the likelihood of substrate 130 cracking. Alternatively, if improved deposition rates could be obtained at conventional temperatures, this would improve production rates and consequently reduce per-unit energy costs.

Hence, it is highly desirable to improve techniques for deposition of films using spray pyrolysis.

### 3. BRIEF SUMMARY OF THE INVENTION

The present invention is directed to deposition of films using spray pyrolysis. More particularly, the invention provides methods and systems for forming functionally graded films using spray pyrolysis. Merely by way of example, the invention has been applied to the spray pyrolysis of functionally graded CdS films for photovoltaic modules. But it would be recognized that the invention has a much broader range of applicability.

According to at least one embodiment, a method for forming a plurality of cadmium-sulfide layers includes preparing at least a first solution and a second solution. The first solution for forming a first cadmium-sulfide layer and the second solution for forming a second cadmium-sulfide layer. The method for forming a plurality of cadmium-sulfide layers further includes loading at least the first solution and the second solution into a pyrolysis-deposition system and placing a target structure into the pyrolysis-depositions system. The pyrolysis-deposition system includes one or more first nozzles and one or more second nozzles. The one or more first nozzles and the one or more second nozzles being different. The method for forming a plurality of cadmium-sulfide layers further includes spraying the first solution through the one or more first nozzles towards the target structure, foiining, from the sprayed first solution, the first cadmium-sulfide layer, directly or indirectly, on the target structure, spraying the second solution through the one or more second nozzles towards the target structure with at least the first cadmium-sulfide layer, and forming, from the sprayed second solution, the second cadmium-sulfide layer directly or indirectly, on the target structure. The first cadmium-sulfide layer includes a first cadmium-sulfide material the second cadmium-sulfide layer includes a second cadmium-sulfide material. The first solution includes a solute corresponding to a first solute concentration. The second solution includes the solute corresponding to a second solute concentration. The first solute concentration and the second solute concentration are different. The first cadmium-sulfide material and the second cadmium-sulfide material are different in at least one material property.

According to another embodiment, a method for forming a photovoltaic module includes providing a substrate and depositing one or more first electrodes directly or indirectly on the substrate. The method for forming a photovoltaic module further includes spraying a first solution through one or more first nozzles towards at least the substrate and forming, from the sprayed first solution, a first cadmium-sulfide layer, directly or indirectly, on the substrate. The first cadmium-sulfide layer includes a first cadmium-sulfide material. The method for forming a photovoltaic module further includes spraying a second solution through one or more second nozzles towards at least the substrate and forming, from the sprayed second solution, a second cadmium-sulfide layer, directly or indirectly, on the substrate. The second cadmium-sulfide layer includes a second cadmium-sulfide material. The method for forming a photovoltaic module further includes depositing a cadmium-telluride layer, directly or indirectly, on the second cadmium-sulfide layer and depositing one or more second electrodes at least partially on the cadmium-telluride layer. The first solution includes a solute corresponding to a first solute concentration. The second solution includes the solute corresponding to a second solute concentration. The first solute concentration and the second solute concentration are different. The first cadmium-sulfide material and the second cadmium-sulfide material are different in at least one material property.

According to yet another embodiment, a photovoltaic module with at least two cadmium-sulfide layers includes a substrate and one or more first electrodes directly or indirectly on the substrate. The photovoltaic module further includes a first cadmium-sulfide layer, directly or indirectly, on the substrate. The first cadmium-sulfide layer including a first cadmium-sulfide material. The photovoltaic module further includes a second cadmium-sulfide layer, directly or indirectly, on the substrate. The second cadmium-sulfide layer including a second cadmium-sulfide material. The photovoltaic module further includes a cadmium-telluride layer, directly or indirectly, on the second cadmium-sulfide layer and one or more second electrodes at least partially on the cadmium-telluride layer. The first cadmium-sulfide material and the second cadmium-sulfide material are different in at least one material property.

According to yet another embodiment, a system for forming cadmium-sulfide layers includes a first liquid supply for providing a first solution and a second liquid supply for providing a second solution. The first solution includes a cadmium-containing solute corresponding to a first concentration, a sulfur-containing solute corresponding to a second concentration, and water. The second solution includes a second liquid supply for providing a second solution including the cadmium-containing solute corresponding to a third concentration, the sulfur-containing solute corresponding to a fourth concentration, and water. The system for forming cadmium-sulfide layers further includes a holder configured to support a target structure, one or more heating devices configured to heat the target structure, one or more first nozzles configured to spray the first solution towards the target structure, and one or more second nozzles configured to spray the second solution towards the target structure. A first distance between the one or more first nozzles and the target structure is configured to be adjustable. A second distance between the one or more second nozzles and the target structure is configured to be adjustable. The first concentration and the third concentration are different or the second concentration and the fourth concentration are different. The system for forming cadmium-sulfide layers is further configured to form a first cadmium-sulfide layer, directly or indirectly, on the target structure using the sprayed first solution and to form a second cadmium-sulfide layer, directly or indirectly, on the target structure using the sprayed second solution. The second cadmium-sulfide material being different from the first cadmium-sulfide material in at least one material property.

Depending upon the embodiment, one or more of these benefits may be achieved. These benefits and various additional objects, features, and advantages of the present invention can be fully appreciated with reference to the detailed description and accompanying drawings that follow.

### 4. BRIEF DESCRIPTION OF THE DRAWINGS

FIG. 1 is a simplified diagram of a conventional photovoltaic module.

FIG. 2 is a simplified diagram of a conventional system for deposition of films on a substrate using spray pyrolysis.

FIG. 3 is a simplified diagram of a photovoltaic module including a functionally graded CdS layer according to one embodiment of the present invention.

FIG. 4 is a simplified diagram of the functionally graded CdS layer as part of the photovoltaic module according to one embodiment of the present invention.

FIG. 5 is a simplified diagram of the functionally graded CdS layer as part of the photovoltaic module according to another embodiment of the present invention.

FIG. 6 is a simplified diagram of the functionally graded CdS layer as part of the photovoltaic module according to yet another embodiment of the present invention.

FIG. 7 is a simplified diagram of the functionally graded CdS layer as part of the photovoltaic module according to yet another embodiment of the present invention.

FIG. 8 is a simplified diagram showing a method for forming the photovoltaic module including the functionally graded CdS layer according to one embodiment of the present invention.

FIG. 9 is a simplified diagram showing the process for forming a functionally graded CdS layer as part of the method for forming the photovoltaic module according to one embodiment of the present invention.

FIG. 10 is a simplified diagram showing a system for forming the functionally graded CdS layer using spray pyrolysis according to one embodiment of the present invention.

FIG. 11 is a simplified diagram of the functionally graded CdS layer as shown in FIG. 7 prior to the planarization process according to one embodiment of the present invention.

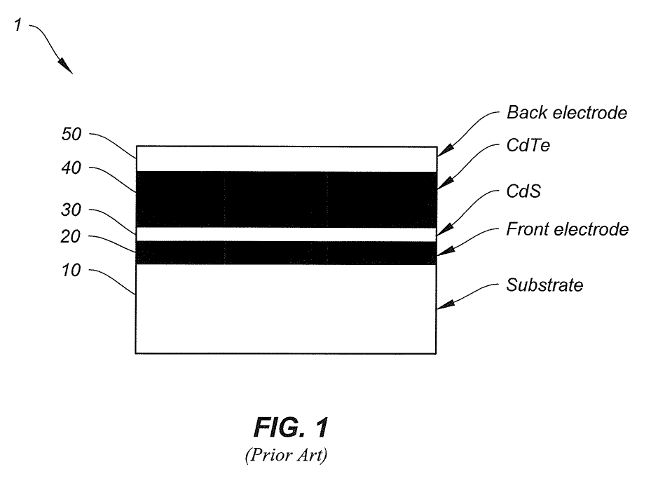

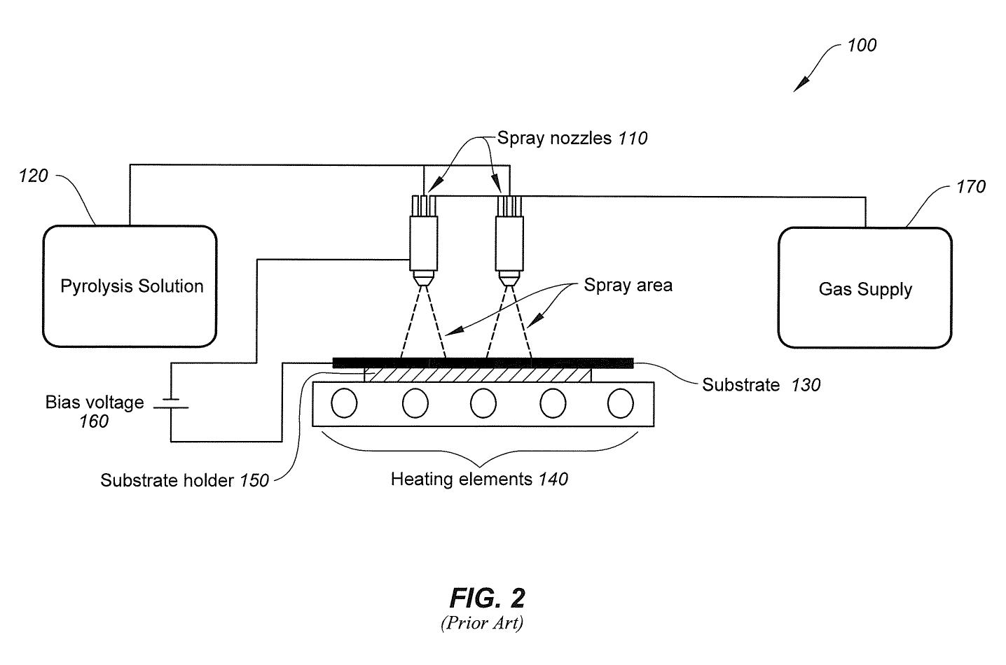

### 5. DETAILED DESCRIPTION OF THE INVENTION

The present invention is directed to deposition of films using spray pyrolysis. More particularly, the invention provides methods and systems for forming functionally graded films using spray pyrolysis. Merely by way of example, the invention has been applied to the spray pyrolysis of functionally graded CdS films for photovoltaic modules. But it would be recognized that the invention has a much broader range of applicability.

Improvements in the deposition rate of a film using spray pyrolysis are also obtained by altering the composition of the pyrolysis solution. For example, by altering the concentration of the one or more solutes in the pyrolysis solution the deposition rate of the resulting film is altered as well. In another example, altering the flow rate of the pyrolysis solution through the spray nozzles also alters the deposition rate of the resulting film. In yet another example, altering both the concentration of the one or more solutes in the pyrolysis solution and the flow rate also alters the deposition rate of the resulting film.

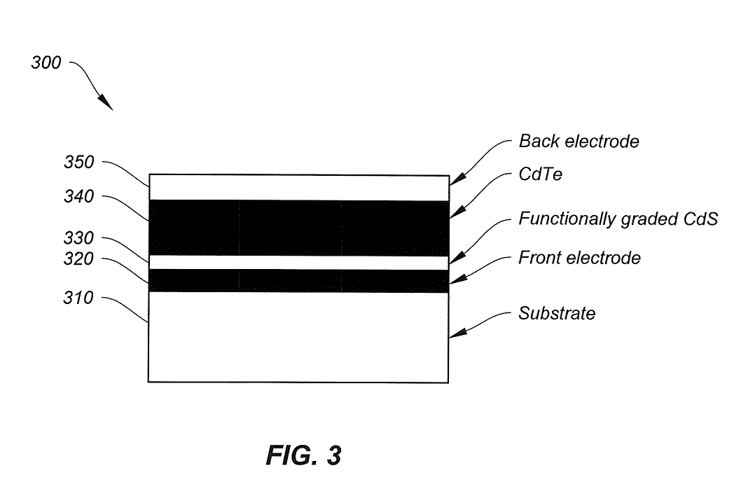

FIG. 3 is a simplified diagram of a photovoltaic module including a functionally graded CdS layer according to one embodiment of the present invention. This diagram is merely an example, which should not unduly limit the scope of the claims. One of ordinary skill in the art would recognize many variations, alternatives, and modifications. According to one embodiment, the photovoltaic module 300 is formed on a substrate 310. For example, the substrate 310 includes glass. In another example, the substrate 310 is about 3 mm in thickness. In yet another example, the substrate 310 is transparent to allow a light source (i.e., the sun) that illuminates the photovoltaic module 300 to pass through to the active layers below. In yet another example, the substrate 310 forms what is generally referred to as the front side of photovoltaic module 300.

According to another embodiment, the photovoltaic module 300 includes at least four layers formed on the substrate 310. In one example, the first layer formed on the substrate 310 includes one or more front electrodes 320 formed using a transparent conductive oxide (i.e., TCO). In another example, the one or more front electrodes 320 are typically between 200 nm and 700 nm in thickness.

According to yet another embodiment, a functionally graded CdS layer 330 (e.g., a functionally graded CdS thin film) is formed over the layer containing the one or more front electrodes 320. For example, the functionally graded CdS layer 330 includes two or more CdS materials. In another example, the functionally graded CdS layer 330 is between 50 nm and 400 nm in thickness. In yet another example, the two or more CdS materials in the functionally graded CdS layer 330 have one or more properties that are significantly different from each other. In yet another example, the two or more CdS materials have one or more different optical properties, one or more different electrical properties, one or more different crystal structures, and/or one or more different reactive properties in photovoltaic applications. In yet another example, the functionally graded CdS layer 330 is fabricated by forming the two or more CdS materials at different deposition rates.

According to yet another embodiment, use of the functionally graded CdS layer improves the deposition rate of the CdS layer in a photovoltaic module 300, while maintaining properties of a CdS layer that is deposited at a slower deposition rate.

As discussed above and further emphasized here, FIG. 3 is merely an example, which should not unduly limit the scope of the claims. One of ordinary skill in the art would recognize many variations, alternatives, and modifications. In some embodiments, one or more of the layers 320, 330, 340 and 350 are discontiguous. For example, one or more other materials and/or one or more other structures are present between the regions of materials in one or more of the layers 320, 330, 340 and 350. In certain embodiments, one or more of the layers 320, 330, 340 and 350 are deposited directly or indirectly on the layer below them.

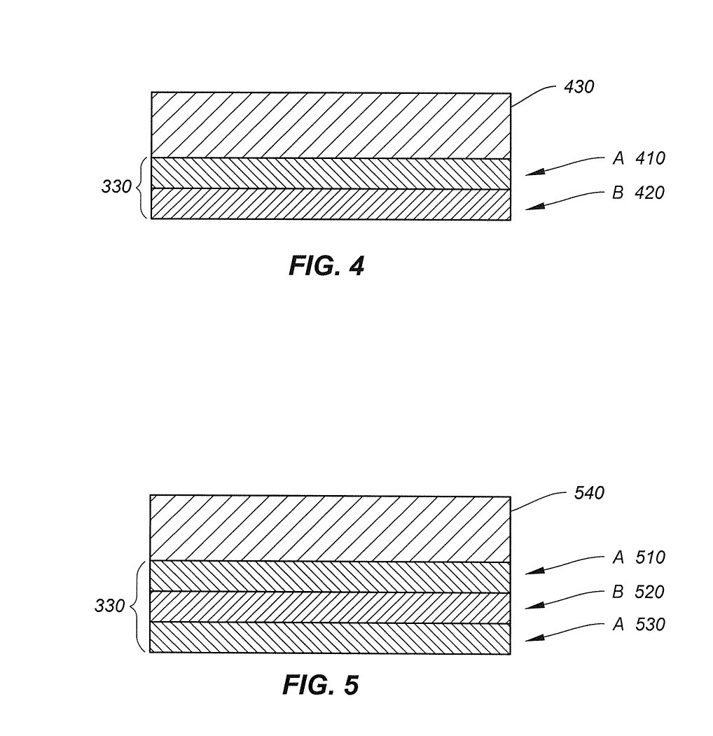

FIG. 4 is a simplified diagram of the functionally graded CdS layer 330 as part of the photovoltaic module 300 according to one embodiment of the present invention. This diagram is merely an example, which should not unduly limit the scope of the claims. One of ordinary skill in the art would recognize many variations, alternatives, and modifications. For example, the functionally graded CdS layer 330 includes a layer A of CdS 410 and a layer B of CdS 420. In another example, the layer A of CdS 410 is deposited in an atomic-layer-by-atomic-layer mode using a slow deposition process. In yet another example, the layer A of CdS 410 is deposited using a spray pyrolysis process with a low liquid flow rate. In yet another example, the layer A of CdS 410 has a dense structure, high transparency, one or more superior electrical properties, and/or one or more superior optical properties. In yet another example, the layer A of CdS 410 is deposited on an intermediate structure 430. In yet another example, the intermediate structure 430 is the layer containing the one or more front electrodes 320. In yet another example, the intermediate structure 430 is a barrier layer.

According to yet another embodiment, the layer B of CdS 420 is deposited by a fast deposition process onto the layer A of CdS 410. For example, the layer B of CdS 420 is deposited using a spray pyrolysis process with a high liquid flow rate. In another example, the layer B of CdS 420 has a less dense structure, lower transparency, one or more less superior electrical properties, and/or one or more less superior optical properties. In yet another example, the layer A of CdS 410 is deposited at a slower rate than the layer B of CdS 420. In yet another example, the layer A of CdS 410 is more tightly packed than the layer B of CdS 420. In yet another example, the layer A of CdS 410 is less porous and thus more difficult to consume during chemical reactions than the layer B of CdS 420. In yet another example, the layer A of CdS 410 is harder and thus more difficult to planarize by, for example, one or more chemical processes, one or more mechanical processes, and/or one or more chemical-mechanical processes than the layer B of CdS 420. In yet another example, the layer B of CdS 420 is partially or fully consumed during the reaction growth of a subsequently deposited layer, such as during a subsequently applied CdTe absorber crystallization process.

FIG. 5 is a simplified diagram of the functionally graded CdS layer 330 as part of the photovoltaic module 300 according to another embodiment of the present invention. This diagram is merely an example, which should not unduly limit the scope of the claims. One of ordinary skill in the art would recognize many variations, alternatives, and modifications.

For example, the functionally graded CdS layer 330 includes a first layer A of CdS 510, a layer B of CdS 520, and a second layer A of CdS 530. In another example, the first layer A of CdS 510 is deposited using a slow deposition process. In yet another example, the first layer A of CdS 510 is deposited using a spray pyrolysis process with a low liquid flow rate. In yet another example, the first layer A of CdS 510 is deposited on an intermediate structure 540. In yet another example, the layer B of CdS 520 is deposited using a fast deposition process. In yet another example, the layer B of CdS 520 is deposited using a spray pyrolysis process with a high liquid flow rate. In yet another example, the layer B of CdS 520 is deposited on the first layer A of CdS 510. In yet another example, the second layer A of CdS 530 is deposited using a slow deposition process. In yet another example, the second layer A of CdS 530 is deposited using a spray pyrolysis process with a low liquid flow rate. In yet another example, the second layer A of CdS 530 is deposited on the layer B of CdS 520. In yet another example, the first layer A of CdS 510 and the second layer A of CdS 530 are deposited using the same deposition process.

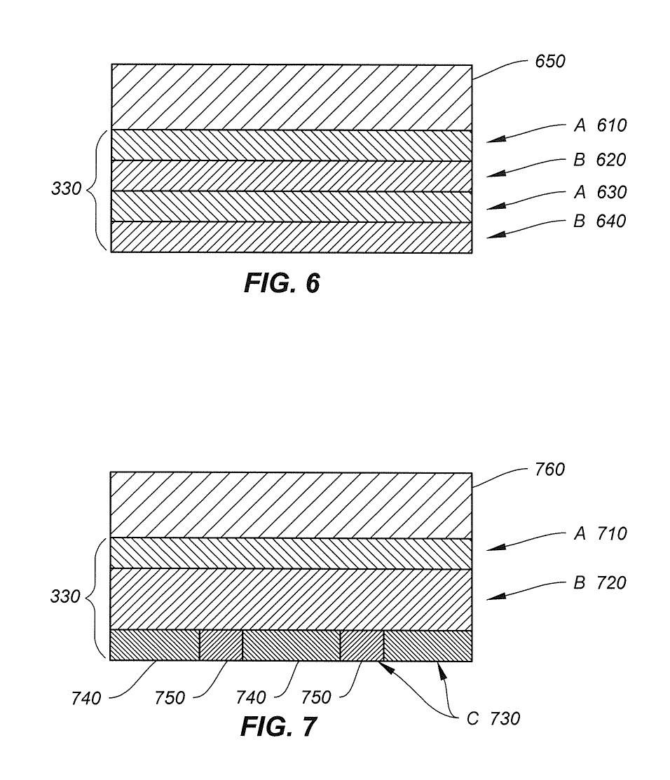

FIG. 6 is a simplified diagram of the functionally graded CdS layer 330 as part of the photovoltaic module 300 according to yet another embodiment of the present invention. This diagram is merely an example, which should not unduly limit the scope of the claims. One of ordinary skill in the art would recognize many variations, alternatives, and modifications.

For example, the functionally graded CdS layer 330 includes a first layer A of CdS 610, a first layer B of CdS 620, a second layer A of CdS 630, and a second layer B of CdS 640. In another example, the first layer A of CdS 610 is deposited using a slow deposition process. In yet another example, the first layer A of CdS 610 is deposited using a spray pyrolysis process with a low liquid flow rate. In yet another example, the first layer A of CdS 610 is deposited on an intermediate structure 650. In yet another example, the first layer B of CdS 620 is deposited using a fast deposition process. In yet another example, the first layer B of CdS 620 is deposited using a spray pyrolysis process with a high liquid flow rate. In yet another example, the first layer B of CdS 620 is deposited on the first layer A of CdS 610. In yet another example, the second layer A of CdS 630 is deposited using a slow deposition process. In yet another example, the second layer A of CdS 630 is deposited using a spray pyrolysis process with a low liquid flow rate. In yet another example, the second layer A of CdS 630 is deposited on the first layer B of CdS 620. In yet another example, the second layer B of CdS 640 is deposited using a fast deposition process. In yet another example, the second layer B of CdS 640 is deposited using a spray pyrolysis process with a high liquid flow rate. In yet another example, the second layer B of CdS 640 is deposited on the second layer A of CdS 630. In yet another example, the first layer A of CdS 610 and the second layer A of CdS 630 are deposited using the same deposition process. In yet another example, the first layer B of CdS 620 and the second layer B of CdS 640 are deposited using the same deposition process. In yet another example, the second layer B of CdS 640 is partially or fully consumed during the reaction growth of a subsequently deposited layer, such as during a subsequently CdTe absorber crystallization process.

FIG. 7 is a simplified diagram of the functionally graded CdS layer 330 as part of the photovoltaic module 300 according to yet another embodiment of the present invention. This diagram is merely an example, which should not unduly limit the scope of the claims. One of ordinary skill in the art would recognize many variations, alternatives, and modifications.

For example, the functionally graded CdS layer 330 includes a layer A of CdS 710, a layer B of CdS 720, and a layer C of CdS 730. In another example, the layer A of CdS 710 is deposited using a slow deposition process. In yet another example, the layer A of CdS 710 is deposited using a spray pyrolysis process with a low liquid flow rate. In yet another example, the layer A of CdS 710 is deposited on an intermediate structure 760. In yet another example, the layer B of CdS 720 is deposited using a fast deposition process. In yet another example, the layer B of CdS 720 is deposited using a spray pyrolysis process with a high liquid flow rate. In yet another example, the layer B of CdS 720 is deposited on the layer A of CdS 710. In yet another example, the layer C of CdS 730 includes a first CdS material 740 similar to the material in the layer A of CdS 710 and a second CdS material 750 similar to the material in the layer B of CdS 720. In yet another example, the first CdS material 740 forms most of the layer C of CdS 730 with isolated islands of the second CdS material 750. In yet another example, the layer C of CdS 730 is deposited on the layer B of CdS 720.

As discussed above and further emphasized here, FIG. 7 is merely an example, which should not unduly limit the scope of the claims. One of ordinary skill in the art would recognize many variations, alternatives, and modifications. For example, the layer C of CdS 730 is deposited directly on the intermediate structure 760 and the layer A of CdS 710 and the layer B of CdS 720 are omitted.

Referring back to FIG. 3, according to some embodiments, the photovoltaic module 300 includes a CdTe layer 340. For example, the CdTe layer 340 is formed over the functionally graded CdS layer 330. In another example, the CdTe layer 340 is between 1000 nm and 5000 nm in thickness.

According to certain embodiments, the photovoltaic module 300 includes a back electrode layer 350. For example, the back electrode layer 350 is formed over the CdTe layer 340. In another example, the back electrode layer 350 includes one or more back electrodes. In yet another example, the back electrode layer 350 is formed using one or more metals. In yet another example, the back electrode layer 350 is between 100 nm and 3000 nm in thickness.

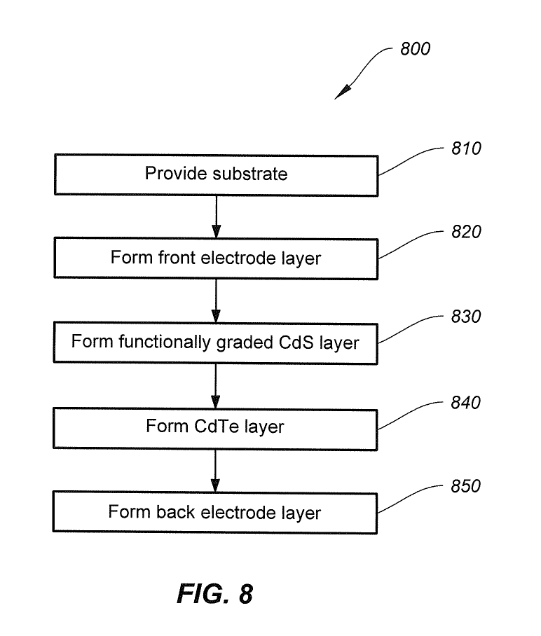

FIG. 8 is a simplified diagram showing a method for forming the photovoltaic module 300 including the functionally graded CdS layer 330 according to one embodiment of the present invention. This diagram is merely an example, which should not unduly limit the scope of the claims. One of ordinary skill in the art would recognize many variations, alternatives, and modifications. As shown in FIG. 8, a method 800 for forming the photovoltaic module 300 includes a process 810 for providing a substrate; a process 820 for forming a front electrode layer; a process 830 for forming a functionally graded CdS layer; a process 840 for forming a CdTe layer; and a process 850 for forming a back electrode layer.

At the process 810, a substrate is provided. For example, the substrate includes glass. In another example, the substrate is the substrate 310. At the process 820, a front electrode layer is formed. For example, the front electrode layer is formed using transparent conductive oxide. In another example, the front electrode layer is the front electrode layer 320. At the process 830, functionally graded CdS layer is formed. For example, the functionally graded CdS layer includes two or more CdS materials. In another example, the functionally graded CdS layer is the functionally graded CdS layer 330. At the process 840, a CdTe layer is formed. For example, the CdTe layer is the CdTe layer 340. At the process 850, a back electrode layer is formed. For example, the back electrode layer is formed using one or more metals. In another example, the back electrode layer is the back electrode layer 350.

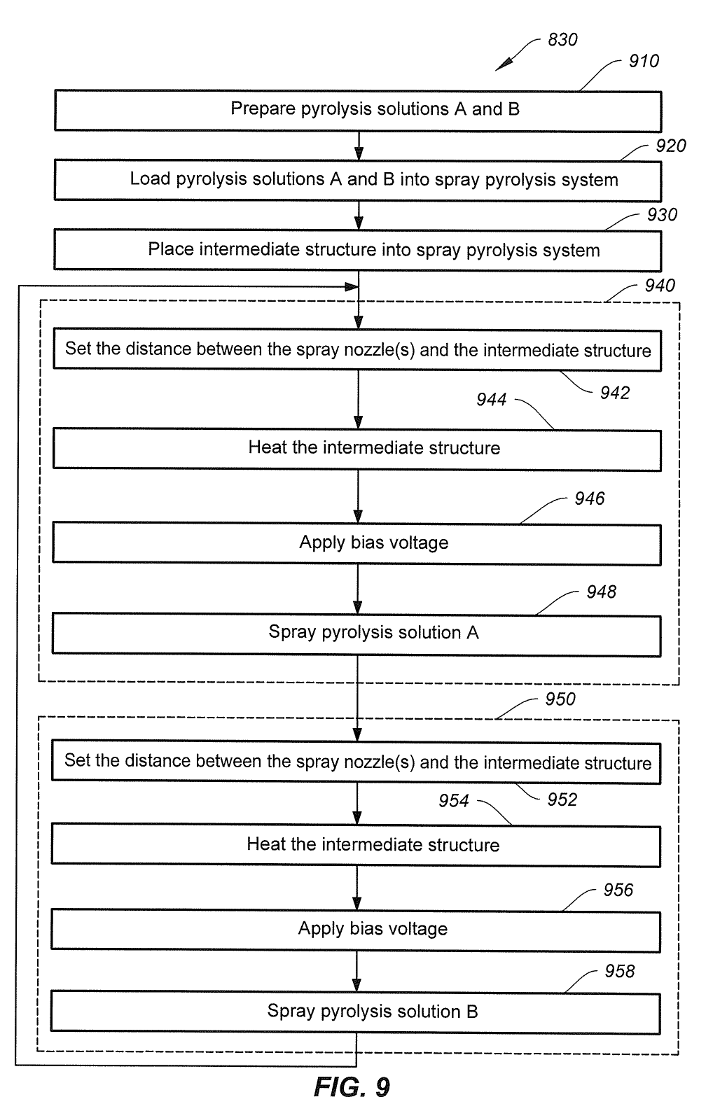

FIG. 9 is a simplified diagram showing the process 830 for forming a functionally graded CdS layer 330 as part of the method 800 for forming the photovoltaic module 300 according to one embodiment of the present invention. This diagram is merely an example, which should not unduly limit the scope of the claims. One of ordinary skill in the art would recognize many variations, alternatives, and modifications. As shown in FIG. 9, a process 830 of forming a functionally graded CdS layer includes a process 910 for preparing a pyrolysis solution A and a pyrolysis solution B; a process 920 for loading the pyrolysis solution A and the pyrolysis solution B into a spray pyrolysis system; a process 930 for placing an intermediate structure into the spray pyrolysis system; a process 940 for depositing a layer A of CdS on the intermediate structure; and a process 950 for depositing a layer B of CdS on the intermediate structure.

At the process 910, a pyrolysis solution A and a pyrolysis solution B are prepared. For example, the pyrolysis solution A includes one or more solvents. In another example, the one or more solvents include water.

In another embodiment, the pyrolysis solution A includes one or more solutes. For example, the one or more solutes include cadmium chloride (i.e., a cadmium containing solute, e.g., CdCl₂). In another example, the concentration of cadmium chloride varies from 0.001 mol. to 0.1 mol. In yet another example, the one or more solutes includes thiourea (i.e., a sulfur containing solute, e.g., an organosulfur compound SC(NH₂)₂.) In yet another example, the concentration of thiourea varies from 0.001 mol. to 0.1 mol. In yet another example, the concentrations of cadmium chloride and thiourea are the same. In yet another example, the concentrations of cadmium chloride and thiourea are different. In yet another example, the pyrolysis solution A is used to create layers of cadmium sulfide (i.e., CdS).

In yet another embodiment, the pyrolysis solution B includes one or more solvents. For example, the one or more solvents include water.

In yet another embodiment, the pyrolysis solution B includes one or more solutes. For example, the one or more solutes include cadmium chloride (i.e., a cadmium containing solute, e.g., CdCl₂). In another example, the concentration of cadmium chloride varies from 0.2 mol. to 1.0 mol. In yet another example, the one or more solutes includes thiourea (i.e., a sulfur containing solute, e.g., an organosulfur compound SC(NH₂)₂.) In yet another example, the concentration of thiourea varies from 0.2 mol. to 1.0 mol. In yet another example, the concentrations of cadmium chloride and thiourea are the same. In yet another example, the concentrations of cadmium chloride and thiourea are different. In yet another example, the pyrolysis solution B is used to create layers of cadmium sulfide (i.e., CdS).

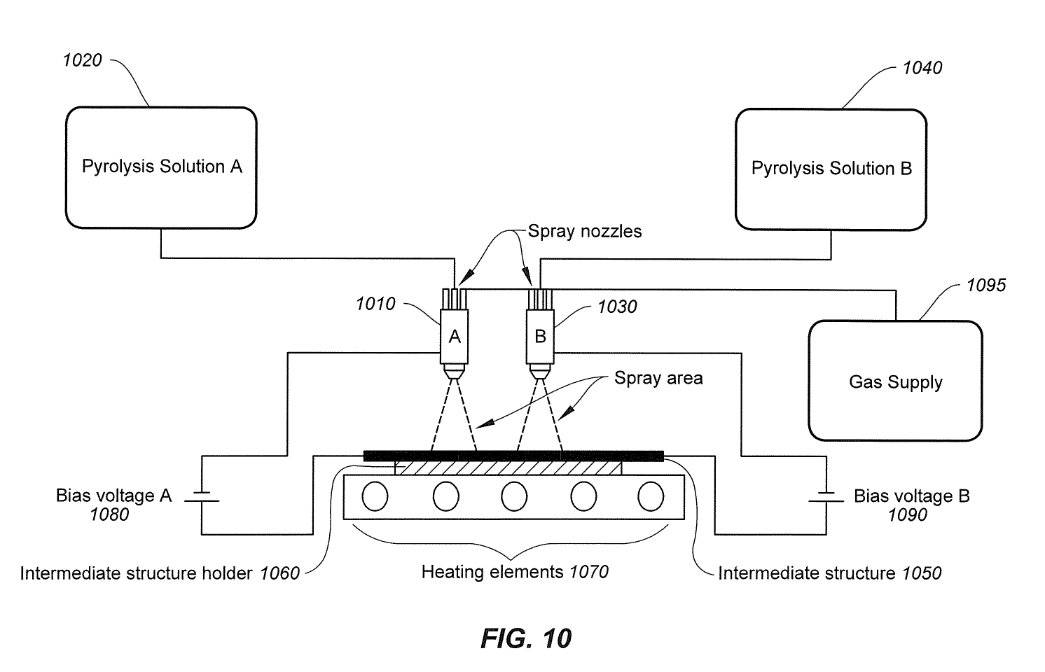

At the process 920 the pyrolysis solution A and the pyrolysis solution B are loaded into a spray pyrolysis system. FIG. 10 is a simplified diagram showing a system for forming the functionally graded CdS layer 330 using spray pyrolysis according to one embodiment of the present invention. This diagram is merely an example, which should not unduly limit the scope of the claims. One of ordinary skill in the art would recognize many variations, alternatives, and modifications. For example, as shown in FIG. 10, the spray pyrolysis system 1000 (e.g., pyrolysis-deposition system) includes one or more spray nozzles A 1010 to spray the pyrolysis solution A 1020 towards an intermediate structure 1050 (e.g., a target structure) positioned via an intermediate structure holder 1060. In another example, the spray pyrolysis system 1000 includes one or more spray nozzles B 1030 to spray the pyrolysis solution B 1040 towards the intermediate structure 1050.

At the process 930, the intermediate structure 1050 is placed into the spray pyrolysis system 1000. For example, the intermediate structure 1050 is placed on the inteimmediate structure holder 1060. In another example, the intermediate structure 1050 is placed into the intermediate structure holder 1060. In yet another example, the intermediate structure holder 1060 positions the intermediate structure 1050 between the one or more spray nozzles A 1010 and one or more heating elements 1070 (e.g., heating devices). In yet another example, the intermediate structure holder 1060 positions the intermediate structure 1050 between the one or more spray nozzles B 1030 and the one or more heating elements 1070. In yet another example, the intermediate structure 1050 could be fed by various automated methods into the spray pyrolysis system 1000 for positioning via the intermediate structure holder 1060.

At the process 940, a layer A of CdS is deposited on the intermediate structure 1050. For example, the process 940 includes a process 942 for setting the distance between the one or more spray nozzles A 1010 and the intermediate structure 1050, a process 944 for heating the intermediate structure 1050, a process 946 for applying a bias voltage A 1080, and a process 948 for spraying the pyrolysis solution A 1020.

At the process 942, the distance between the one or more spray nozzles A 1010 and the intermediate structure 1050 is set based at least in part on the desired properties of the layer A of CdS to be created. In yet another example, the distance between the one or more spray nozzles A 1010 and the intermediate structure 1050 is set between 10 cm and 30 cm. In yet another example, the distance between the one or more spray nozzles A 1010 and the intermediate structure 1050 has been previously set during a previous process and is not reset.

At the process 944, the intermediate structure 1050 is heated by the one or more heating elements 1060. For example, the temperature of the intermediate structure 1050 is set based at least in part on the desired properties of the layer A of CdS to be created. In another example, the temperature of the intermediate structure 1050 is set based at least in part on the desired balance between deposition rate and energy consumption. In yet another example, the intermediate structure 1050 is heated to a temperature between 280° C. and 500° C. In yet another example, the intermediate structure 1050 has been previously heated to the desired temperature during a previous process and does not require heating other than to retain the desired temperature.

At the process 946, a bias voltage A 1080 is optionally applied between the one or more spray nozzles A 1010 and the intermediate structure 1050. For example, the bias voltage A 1080 is set based at least in part on the desired properties of the layer A of CdS to be created. In another example, the bias voltage A 1080 is set based at least in part on a desired material utilization requirement. In yet another example, the bias voltage A 1080 is set in the range of 500 volts to 10 kilovolts. In yet another example, the bias voltage A 1080 has been previously applied during a previous process and does not need to be reapplied.

At the process 948, the pyrolysis solution A 1020 is sprayed using the one or more spray nozzles A 1010. In one example, a single spray nozzle 1010 is utilized to spray the pyrolysis solution A 1020 to create the layer A of CdS on the intermediate structure 1050. In another example, multiple spray nozzles A 1010 are utilized to create the layer A of CdS on the intermediate structure 1050. In yet another example, the intermediate structure 1050 is a substrate. In yet another example, the intermediate structure 1050 is a substrate with one or more previous layers and/or one or more previous films formed on it. In yet another example, the one or more previous layers and/or the one or more previous films include a previously deposited front electrode layer 320. In yet another example, the one or more previous layers and/or the one or more previous films include previously deposited layers of CdS.

According to some embodiments, atomization of the pyrolysis solution A 1020 at the point of each of the one or more spray nozzles A 1010 is created using gas, mechanical, and/or hydraulic atomization techniques. For example, the spray rate of the pyrolysis solution A 1020 is constant. In another example, the spray rate of the pyrolysis solution A 1020 is modulated between two or more spray rates. In yet another example, the one or more spray rates and/or spray durations is set based at least in part on the desired properties of the layer A of CdS to be created. In yet another example, the one or more spray rates is between 1 ml/min and 10 ml/min. In yet another example, the spray duration is between 30 seconds and 40 minutes. In yet another example, the deposition rate of the layer A of CdS is monitored during spraying to control the layer created. In yet another example, the layer A of CdS is the layer A of CdS 410, the first layer A of CdS 510, the second layer A of CdS 530, the first layer A of CdS 610, the second layer A of CdS 630, the layer A of CdS 710, and/or the first CdS material 740 of the layer C of CdS 730.

According to some embodiments, as one or more droplets of the pyrolysis solution A 1020 approach the surface of the intermediate structure 1050, the one or more solvents vaporize and the one or more solutes become one or more vapors. Then, the one or more vapors form the layer A of CdS on the surface of the intermediate structure 1050. In another embodiment, one or more droplets of the pyrolysis solution A 1020 reach the surface of the intermediate structure 1050. Then, with the one or more solvents still present in the pyrolysis solution A 1020 on the surface of the intermediate structure 1050, the layer A of CdS is formed on the surface of the intermediate structure 1050 as the one or more solvents in the pyrolysis solution A 1020 vaporize. In yet another embodiment, vaporization both between the one or more spray nozzles A 1010 and the intermediate structure 1050 and on the surface of the intermediate structure 1050 occur in the same deposition process. In yet another embodiment, spray pyrolysis also utilizes a gas supply 1095 made available to the one or more spray nozzles A 1010. For example, the gas supply 1095 is used to atomize the pyrolysis solution A 1020. In another example, the gas supply 1095 controls the flow of the pyrolysis solution A 1020 through the one or more spray nozzles A 1010 towards the intermediate structure 1050. In yet another example, nitrogen gas is provided by the gas supply 1095.

According to yet another embodiment, each of the parameters in the pyrolysis process 940 is mutually dependent upon each other. In yet another embodiment, each of the parameters in the pyrolysis process 940 are set based at least in part on the desired properties of the layer A of CdS to be created. For example, depending upon the layer A of CdS desired, the distance between the one or more spray nozzles A 1010 and the intermediate structure 1050, the temperature of the intermediate structure 1050, the optional bias voltage A 1080 between the one or more spray nozzles A 1010 and the intermediate structure 1050, and the spray rate and duration are set based in part on each other and the properties of the pyrolysis solution A 1020 being used. In another example, the pyrolysis solution A 1020 includes a cadmium chloride concentration of 0.1 mol., and a thiourea concentration of 0.1 mol., and the pyrolysis solution A 1020 is sprayed with a flow rate of 8 ml/min. for five minutes towards the intermediate structure 1050 that is heated to 350° C. with a distance of 20 cm between the one or more spray nozzles A 1010 and the intermediate structure 1050 and with a bias voltage A 1080 of 1000 volts, resulting in a layer A of CdS of approximately 150

At the process 950, a layer B of CdS is deposited on the intermediate structure 1050. For example, the process 950 includes a process 952 for adjusting the distance between the one or more spray nozzles B 1030 and the intermediate structure 1050, a process 954 for heating the intermediate structure 1050, a process 956 for applying a bias voltage B 1090, and a process 958 for spraying the pyrolysis solution B 1040.

At the process 952, the distance between the one or more spray nozzles B 1030 and the intermediate structure 1050 is set based at least in part on the desired properties of the layer B of CdS to be created. In yet another example, the distance between the one or more spray nozzles B 1030 and the intermediate structure 1050 is set between 10 cm and 30 cm. In yet another example, the distance between the one or more spray nozzles B 1030 and the intermediate structure 1050 has been previously set during a previous process and is not reset.

At the process 954, the intermediate structure 1050 is heated by the one or more heating elements 1060. For example, the temperature of the intermediate structure 1050 is set based at least in part on the desired properties of the layer B of CdS to be created. In another example, the temperature of the intermediate structure 1050 is set based at least in part on the desired balance between deposition rate and energy consumption. In yet another example, the intermediate structure 1050 is heated to a temperature between 280° C. and 500° C. In yet another example, the intermediate structure 1050 has been previously heated to the desired temperature during a previous process and does not require heating other than to retain the desired temperature.

At the process 956, a bias voltage B 1090 is optionally applied between the one or more spray nozzles B 1030 and the intermediate structure 1050. For example, the bias voltage B 1090 is set based at least in part on the desired properties of the layer B of CdS to be created. In another example, the bias voltage B 1090 is set based at least in part on a desired material utilization requirement. In yet another example, the bias voltage B 1090 is set in the range of 500 volts to 10 kilovolts. In yet another example, the bias voltage A 1080 has been previously applied during a previous process and does not need to be reapplied. In yet another example the bias voltage B 1090 and the bias voltage A 1080 are the same. In yet another example, the one or more spray nozzles A 1010 and the one or more spray nozzles B 1030 are coupled to the same voltage potential and either the bias voltage A 1080 or the bias voltage B 1090 is omitted.

At the process 958, the pyrolysis solution B 1040 is sprayed using the one or more spray nozzles B 1030. In one example, a single spray nozzle 1030 is utilized to spray the pyrolysis solution B 1040 to create the layer B of CdS on the intermediate structure 1050. In another example, multiple spray nozzles B 1030 are utilized to create the layer B of CdS on the intermediate structure 1050. In yet another example, the intermediate structure 1050 is a substrate. In yet another example, the intermediate structure 1050 is a substrate with one or more previous layers and/or one or more previous films fanned on it. In yet another example, the one or more previous layers and/or the one or more previous films include a previously deposited front electrode layer 320. In yet another example, the one or more previous layers and/or the one or more previous films include previously deposited layers of CdS.

According to some embodiments, atomization of the pyrolysis solution B 1040 at the point of each of the one or more spray nozzles B 1030 is created using gas, mechanical, and/or hydraulic atomization techniques. For example, the spray rate of the pyrolysis solution B 1040 is constant. In another example, the spray rate of the pyrolysis solution B 1040 is modulated between two or more spray rates. In yet another example, the one or more spray rates and/or spray durations is set based at least in part on the desired properties of the layer B of CdS to be created. In yet another example, the one or more spray rates is between 10 ml/min and 100 ml/min. In yet another example, the spray duration is between 30 seconds and 40 minutes. In yet another example, the deposition rate of the layer B of CdS is monitored during spraying to control the layer created. In yet another example, the layer B of CdS is the layer B of CdS 420, the layer B of CdS 520, the first layer B of CdS 620, the second layer B of CdS 640, the layer B of CdS 720, and/or the second CdS material 770 of the layer C of CdS 730.

According to some embodiments, as one or more droplets of the pyrolysis solution B 1040 approach the surface of the intermediate structure 1050, the one or more solvents vaporize and the one or more solutes become one or more vapors. Then, the one or more vapors form the layer B of CdS on the surface of the intermediate structure 1050. In another embodiment, one or more droplets of the pyrolysis solution B 1040 reach the surface of the intermediate structure 1050. Then, with the one or more solvents still present in the pyrolysis solution B 1040 on the surface of the intermediate structure 1050, the layer B of CdS is foamed on the surface of the intermediate structure 1050 as the one or more solvents in the pyrolysis solution B 1040 vaporize. In yet another embodiment, vaporization both between the one or more spray nozzles B 1030 and the intermediate structure 1050 and on the surface of the intermediate structure 1050 occur in the same deposition process. In yet another embodiment, spray pyrolysis also utilizes a gas supply 1095 made available to the one or more spray nozzles B 1030. For example, the gas supply 1095 is used to atomize the pyrolysis solution B 1040. In another example, the gas supply 1095 controls the flow of the pyrolysis solution B 1040 through the one or more spray nozzles B 1030 towards the intermediate structure 1050. In yet another example, nitrogen gas is provided by the gas supply 1095.

According to yet another embodiment, each of the parameters in the pyrolysis process 950 is mutually dependent upon each other. In yet another embodiment, each of the parameters in the pyrolysis process 950 are set based at least in part on the desired properties of the layer B of CdS to be created. For example, depending upon the layer B of CdS desired, the distance between the one or more spray nozzles B 1030 and the intermediate structure 1050, the temperature of the intermediate structure 1050, the optional bias voltage B 1090 between the one or more spray nozzles B 1030 and the intermediate structure 1050, and the spray rate and duration are set based in part on each other and the properties of the pyrolysis solution B 1040 being used. In another example, the pyrolysis solution B 1040 includes a cadmium chloride concentration of 1.0 mol., and a thiourea concentration of 1.0 mol., and the pyrolysis solution B 1040 sprayed with a flow rate of 8 ml/min. for one minute towards the intermediate structure 1050 that is heated to 350° C. with a distance of 20 cm between the one or more spray nozzles B 1030 and the intermediate structure 1050 and with a bias voltage B 1090 of 1000 volts, resulting in a layer B of CdS of approximately 300 nm.

According to yet another embodiment the process 940 for depositing a layer A of CdS on the substrate and the process 950 for depositing a layer B of CdS on the substrate are repeated as necessary to create the desired functionally graded CdS layer 330. For example, the process 940 and the process 950 are each used once to create the functionally graded CdS layer 330 of FIG. 4. In another example, the process 940 is repeated twice and the process 950 once to create the functionally graded CdS layer 330 of FIG. 5. In yet another example, the process 940 and the process 950 are alternately repeated twice to create the functionally graded CdS layer 330 of FIG. 6. In yet another example, the process 940 and the process 950 are used to create the functionally graded CdS layer 330 of FIG. 7.

As discussed above and further emphasized here, FIGS. 8, 9 and 10 are merely examples, which should not unduly limit the scope of the claims. One of ordinary skill in the art would recognize many variations, alternatives, and modifications. For example, additional pyrolysis solutions with different properties are utilized to form functionally graded CdS layers 330 with layers of CdS with three or more different properties. In another example, functionally graded layers of materials other than CdS are formed. In yet another example, variations on the method 800 and the pyrolysis system 1000 are used in the manufacture of displays, photodiodes, and/or other devices incorporating thin films.

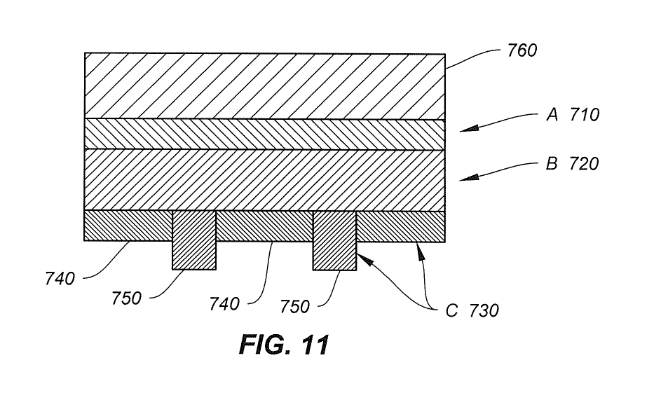

In yet additional embodiments, the process 830 of forming a functionally graded CdS layer 330 also includes a planarization process. FIG. 11 is a simplified diagram of the functionally graded CdS layer 330 as shown in FIG. 7 prior to the planarization process according to one embodiment of the present invention. This diagram is merely an example, which should not unduly limit the scope of the claims. One of ordinary skill in the art would recognize many variations, alternatives, and modifications. For example, during the formation of the functionally graded CdS layer 330 as depicted in the embodiments of FIG. 7, the first CdS material 740 and the second CdS material 750 of the layer C of CdS 730 are deposited at different rates and have different thicknesses as shown in FIG. 10. In another example, the second CdS material 750 is thicker than the first CdS material 740. In some embodiments, the planarization process is used to make the layer C of CdS 730 of uniform or substantially uniform thickness. For example, the planarization process includes a CdTe absorber crystallization process. In another example, the planarization process includes an etching process.

According to at least one embodiment, a method for forming a plurality of cadmium-sulfide layers includes preparing at least a first solution and a second solution. The first solution for forming a first cadmium-sulfide layer and the second solution for forming a second cadmium-sulfide layer. The method for forming a plurality of cadmium-sulfide layers further includes loading at least the first solution and the second solution into a pyrolysis-deposition system and placing a target structure into the pyrolysis-depositions system. The pyrolysis-deposition system includes one or more first nozzles and one or more second nozzles. The one or more first nozzles and the one or more second nozzles being different. The method for forming a plurality of cadmium-sulfide layers further includes spraying the first solution through the one or more first nozzles towards the target structure, forming, from the sprayed first solution, the first cadmium-sulfide layer, directly or indirectly, on the target structure, spraying the second solution through the one or more second nozzles towards the target structure with at least the first cadmium-sulfide layer, and forming, from the sprayed second solution, the second cadmium-sulfide layer directly or indirectly, on the target structure. The first cadmium-sulfide layer includes a first cadmium-sulfide material the second cadmium-sulfide layer includes a second cadmium-sulfide material. The first solution includes a solute corresponding to a first solute concentration. The second solution includes the solute corresponding to a second solute concentration. The first solute concentration and the second solute concentration are different. The first cadmium-sulfide material and the second cadmium-sulfide material are different in at least one material property. For example, the method for forming a plurality of cadmium-sulfide layers is implemented according to at least FIG. 9 and/or FIG. 10.

In another example, forming the second cadmium-sulfide layer includes forming the second cadmium-sulfide layer entirely on the first-cadmium-sulfide layer. In yet another example, forming the second cadmium-sulfide layer includes forming the second-cadmium sulfide layer between one or more regions of the first cadmium-sulfide layer. In yet another example, forming the first cadmium-sulfide layer includes forming the first cadmium-sulfide layer as a contiguous layer. In yet another example, forming the first cadmium-sulfide layer includes forming the first cadmium-sulfide layer as a plurality of discontiguous regions of the first cadmium-sulfide material. In yet another example, forming the second cadmium-sulfide layer includes forming the second cadmium-sulfide layer as a contiguous layer. In yet another example, forming the second cadmium-sulfide layer includes forming the second cadmium-sulfide layer as a plurality of discontiguous regions of the second cadmium-sulfide material.

In yet another example, the method for forming a plurality of cadmium-sulfide layers further includes adjusting a first distance between the one or more first nozzles and the target structure and adjusting a second distance between the one or more second nozzles and the target structure. The forming the first cadmium-sulfide layer includes heating the target structure to a first temperature and forming the second cadmium-sulfide layer includes heating the target structure to a second temperature. In yet another example, the first distance and the second distance are the same. In yet another example, the first temperature and the second temperature are the same.

In yet another example, the method for forming a plurality of cadmium-sulfide layers further includes applying a first bias voltage between the one or more first nozzles and the target structure and applying a second bias voltage between the one or more second nozzles and the target structure. In yet another example, the first bias voltage and the second bias voltage are the same. In yet another example, the method for forming a plurality of cadmium-sulfide layers further includes planarizing at least the second cadmium-sulfide layer.

In yet another example, the first solution includes water, a cadmium-containing solute, and a sulfur-containing solute and the second solution includes water, the cadmium-containing solute, and the sulfur-containing solute. In yet another example, the cadmium-containing solute is present in the first solution with a first concentration of between 0.001 mol. and 0.1 mol., the sulfur-containing solute is present in the first solution with a second concentration of between 0.001 mol. and 0.1 mol, the cadmium-containing solute is present in the second solution with a third concentration of between 0.2 mol. and 1.0 mol., and the sulfur-containing solute is present in the second solution with a fourth concentration of between 0.2 mol. and 1.0 mol. In yet another example, the cadmium-containing solute is cadmium chloride and the sulfur-containing solute is thiourea.

In yet another example, spraying the first solution includes spraying the first solution at a first flow rate. Spraying the second solution includes spraying the second solution at a second flow rate. And, the first flow rate and the second flow rate are different. In yet another example, the material property is selected from a group consisting of electrical properties, crystal structures, and optical reactive properties.

According to another embodiment, a method for forming a photovoltaic module includes providing a substrate and depositing one or more first electrodes directly or indirectly on the substrate. The method for forming a photovoltaic module further includes spraying a first solution through one or more first nozzles towards at least the substrate and forming, from the sprayed first solution, a first cadmium-sulfide layer, directly or indirectly, on the substrate. The first cadmium-sulfide layer includes a first cadmium-sulfide material. The method for forming a photovoltaic module further includes spraying a second solution through one or more second nozzles towards at least the substrate and forming, from the sprayed second solution, a second cadmium-sulfide layer, directly or indirectly, on the substrate. The second cadmium-sulfide layer includes a second cadmium-sulfide material. The method for forming a photovoltaic module further includes depositing a cadmium-telluride layer, directly or indirectly, on the second cadmium-sulfide layer and depositing one or more second electrodes at least partially on the cadmium-telluride layer. The first solution includes a solute corresponding to a first solute concentration. The second solution includes the solute corresponding to a second solute concentration. The first solute concentration and the second solute concentration are different. The first cadmium-sulfide material and the second cadmium-sulfide material are different in at least one material property. For example, the method for forming a photovoltaic module is implemented according to at least FIG. 8, FIG. 9, and/or FIG. 10.

In another example, forming the first cadmium-sulfide layer includes forming the first cadmium-sulfide layer on the one or more first electrodes. In yet another example, forming the second cadmium-sulfide layer includes forming the second cadmium-sulfide layer on the first cadmium-sulfide layer. In yet another example, forming the cadmium-telluride layer includes forming the cadmium-telluride layer on a third cadmium-sulfide layer. In yet another example, the substrate includes glass. In yet another example, the material property is selected from a group consisting of electrical properties, crystal structures, and optical reactive properties.

According to yet another embodiment, a photovoltaic module with at least two cadmium-sulfide layers includes a substrate and one or more first electrodes directly or indirectly on the substrate. The photovoltaic module further includes a first cadmium-sulfide layer, directly or indirectly, on the substrate. The first cadmium-sulfide layer including a first cadmium-sulfide material. The photovoltaic module further includes a second cadmium-sulfide layer, directly or indirectly, on the substrate. The second cadmium-sulfide layer including a second cadmium-sulfide material. The photovoltaic module further includes a cadmium-telluride layer, directly or indirectly, on the second cadmium-sulfide layer and one or more second electrodes at least partially on the cadmium-telluride layer. The first cadmium-sulfide material and the second cadmium-sulfide material are different in at least one material property. For example, the photovoltaic module with at least two cadmium-sulfide layers is implemented according to at least FIG. 3, FIG. 4, FIG. 5, FIG. 6, and/or FIG. 7.

In another example, the material property is selected from a group consisting of electrical properties, crystal structures, and optical reactive properties.

According to yet another embodiment, a system for forming cadmium-sulfide layers includes a first liquid supply for providing a first solution and a second liquid supply for providing a second solution. The first solution includes a cadmium-containing solute corresponding to a first concentration, a sulfur-containing solute corresponding to a second concentration, and water. The second solution includes a second liquid supply for providing a second solution including the cadmium-containing solute corresponding to a third concentration, the sulfur-containing solute corresponding to a fourth concentration, and water. The system for forming cadmium-sulfide layers further includes a holder configured to support a target structure, one or more heating devices configured to heat the target structure, one or more first nozzles configured to spray the first solution towards the target structure, and one or more second nozzles configured to spray the second solution towards the target structure. A first distance between the one or more first nozzles and the target structure is configured to be adjustable. A second distance between the one or more second nozzles and the target structure is configured to be adjustable. The first concentration and the third concentration are different or the second concentration and the fourth concentration are different. The system for forming cadmium-sulfide layers is further configured to form a first cadmium-sulfide layer, directly or indirectly, on the target structure using the sprayed first solution and to form a second cadmium-sulfide layer, directly or indirectly, on the target structure using the sprayed second solution. The second cadmium-sulfide material being different from the first cadmium-sulfide material in at least one material property. For example, the system for forming cadmium-sulfide layers is implemented according to at least FIG. 10.

In another example, the material property is selected from a group consisting of electrical properties, crystal structures, and optical reactive properties. In yet another example, the first concentration and the third concentration are different, and the second concentration and the fourth concentration are different.

Although specific embodiments of the present invention have been described, it will be understood by those of skill in the art that there are other embodiments that are equivalent to the described embodiments. For example, various embodiments and/or examples of the present invention can be combined. Accordingly, it is to be understood that the invention is not to be limited by the specific illustrated embodiments, but only by the scope of the appended claims.

What is claimed is:

1. A method for forming a plurality of cadmium-sulfide layers, the method comprising:
preparing at least a first solution for forming a first cadmium-sulfide layer and a second solution for forming a second cadmium-sulfide layer;
loading at least the first solution and the second solution into a pyrolysis-deposition system, the pyrolysis-deposition system including one or more first nozzles and one or more second nozzles, the one or more first nozzles and the one or more second nozzles being different;
placing a target structure into the pyrolysis-deposition system;
spraying the first solution through the one or more first nozzles towards the target structure;
forming, from the sprayed first solution, the first cadmium-sulfide layer, directly or indirectly, on the target structure, the first cadmium-sulfide layer including a first cadmium-sulfide material;
spraying the second solution through the one or more second nozzles towards the target structure with at least the first cadmium-sulfide layer; and
forming, from the sprayed second solution, the second cadmium-sulfide layer directly or indirectly, on the target structure, the second cadmium-sulfide layer including a second cadmium-sulfide material;
wherein:
the first solution includes a solute corresponding to a first solute concentration;
the second solution includes the solute corresponding to a second solute concentration; and
the first solute concentration and the second solute concentration are different;
wherein the first cadmium-sulfide material and the second cadmium-sulfide material are different in at least one material property.

2. The method of claim 1 wherein the process for forming the second cadmium-sulfide layer includes forming the second cadmium-sulfide layer entirely on the first-cadmium-sulfide layer.

3. The method of claim 1 wherein the process for forming the second cadmium-sulfide layer includes forming the second-cadmium sulfide layer between one or more regions of the first cadmium-sulfide layer.

4. The method of claim 1 wherein the process for forming the first cadmium-sulfide layer includes forming the first cadmium-sulfide layer as a contiguous layer.

5. The method of claim 1 wherein the process for forming the first cadmium-sulfide layer includes forming the first cadmium-sulfide layer as a plurality of discontiguous regions of the first cadmium-sulfide material.

6. The method of claim 1 wherein the process for forming the second cadmium-sulfide layer includes forming the second cadmium-sulfide layer as a contiguous layer.

7. The method of claim 1 wherein the process for forming the second cadmium-sulfide layer includes forming the second cadmium-sulfide layer as a plurality of discontiguous regions of the second cadmium-sulfide material.

8. The method of claim 1, and further comprising:
adjusting a first distance between the one or more first nozzles and the target structure; and
adjusting a second distance between the one or more second nozzles and the target structure;
wherein:
the process for forming the first cadmium-sulfide layer includes heating the target structure to a first temperature; and
the process for forming the second cadmium-sulfide layer includes heating the target structure to a second temperature.

9. The method of claim 8 wherein the first distance and the second distance are the same.

10. The method of claim 8 wherein the first temperature and the second temperature are the same.

11. The method of claim 1, and further comprising:
applying a first bias voltage between the one or more first nozzles and the target structure; and
applying a second bias voltage between the one or more second nozzles and the target structure.

12. The method of claim 11 wherein the first bias voltage and the second bias voltage are the same.

13. The method of claim 1, and further comprising planarizing at least the second cadmium-sulfide layer.

14. The method of claim 1 wherein:
the first solution includes water, a cadmium-containing solute, and a sulfur-containing solute; and
the second solution includes water, the cadmium-containing solute, and the sulfur-containing solute.

15. The method of claim 14 wherein:
the cadmium-containing solute is present in the first solution with a first concentration of between 0.001 mol. and 0.1 mol.;
the sulfur-containing solute is present in the first solution with a second concentration of between 0.001 mol. and 0.1 mol;
the cadmium-containing solute is present in the second solution with a third concentration of between 0.2 mol. and 1.0 mol.; and
the sulfur-containing solute is present in the second solution with a fourth concentration of between 0.2 mol. and 1.0 mol.

16. The method of claim 14 wherein:
the cadmium-containing solute is cadmium chloride; and
the sulfur-containing solute is thiourea.

17. The method of claim 1 wherein:
the process for spraying the first solution includes spraying the first solution at a first flow rate;
the process for spraying the second solution includes spraying the second solution at a second flow rate; and
the first flow rate and the second flow rate are different.

18. The method of claim 1 wherein the material property is selected from a group consisting of electrical properties, crystal structures, and optical reactive properties.

19. A method for forming a photovoltaic module, the method comprising:
providing a substrate;
depositing one or more first electrodes directly or indirectly on the substrate;
spraying a first solution through one or more first nozzles towards at least the substrate;
forming, from the sprayed first solution, a first cadmium-sulfide layer, directly or indirectly, on the substrate, the first cadmium-sulfide layer including a first cadmium-sulfide material;
spraying a second solution through one or more second nozzles towards at least the substrate;
forming, from the sprayed second solution, a second cadmium-sulfide layer, directly or indirectly, on the substrate, the second cadmium-sulfide layer including a second cadmium-sulfide material;
depositing a cadmium-telluride layer, directly or indirectly, on the second cadmium-sulfide layer; and
depositing one or more second electrodes at least partially on the cadmium-telluride layer;
wherein:
the first solution includes a solute corresponding to a first solute concentration;
the second solution includes the solute corresponding to a second solute concentration; and
the first solute concentration and the second solute concentration are different;
wherein the first cadmium-sulfide material and the second cadmium-sulfide material are different in at least one material property.

20. The method of claim 19 wherein the process for forming the first cadmium-sulfide layer includes forming the first cadmium-sulfide layer on the one or more first electrodes.

21. The method of claim 19 wherein the process for forming the second cadmium-sulfide layer includes forming the second cadmium-sulfide layer on the first cadmium-sulfide layer.

22. The method of claim 19 wherein the process for forming the cadmium-telluride layer includes forming the cadmium-telluride layer on a third cadmium-sulfide layer.

23. The method of claim 19 wherein the substrate includes glass.

24. The method of claim 19 wherein the material property is selected from a group consisting of electrical properties, crystal structures, and optical reactive properties.

25. A photovoltaic module with at least two cadmium-sulfide layers, the module comprising:
a substrate;
one or more first electrodes directly or indirectly on the substrate;
a first cadmium-sulfide layer, directly or indirectly, on the substrate, the first cadmium-sulfide layer including a first cadmium-sulfide material;
a second cadmium-sulfide layer, directly or indirectly, on the substrate, the second cadmium-sulfide layer including a second cadmium-sulfide material;
a cadmium-telluride layer, directly or indirectly, on the second cadmium-sulfide layer; and
one or more second electrodes at least partially on the cadmium-telluride layer;
wherein the first cadmium-sulfide material and the second cadmium-sulfide material are different in at least one material property.

26. The module of claim 25 wherein the material property is selected from a group consisting of electrical properties, crystal structures, and optical reactive properties.

27. A system for forming cadmium-sulfide layers, the system comprising:
a first liquid supply for providing a first solution including a cadmium-containing solute corresponding to a first concentration, a sulfur-containing solute corresponding to a second concentration, and water;
a second liquid supply for providing a second solution including the cadmium-containing solute corresponding to a third concentration, the sulfur-containing solute corresponding to a fourth concentration, and water;
a holder configured to support a target structure;
one or more heating devices configured to heat the target structure;
one or more first nozzles configured to spray the first solution towards the target structure; and
one or more second nozzles configured to spray the second solution towards the target structure;
wherein:
a first distance between the one or more first nozzles and the target structure is configured to be adjustable; and
a second distance between the one or more second nozzles and the target structure is configured to be adjustable;
wherein the first concentration and the third concentration are different or the second concentration and the fourth concentration are different;
wherein:
the system is further configured to form a first cadmium-sulfide layer, directly or indirectly, on the target structure using the sprayed first solution; and
the system is further configured to form a second cadmium-sulfide layer, directly or indirectly, on the target structure using the sprayed second solution, the second cadmium-sulfide material being different from the first cadmium-sulfide material in at least one material property.

28. The system of claim 27 wherein the material property is selected from a group consisting of electrical properties, crystal structures, and optical reactive properties.

29. The system of claim 27 wherein the first concentration and the third concentration are different, and the second concentration and the fourth concentration are different.
